(19) United States
(12) Patent Application Publication
(10) Pub. No.: US 2009/0236682 A1
(43) Pub. Date: Sep. 24, 2009

(54) LAYER STACK INCLUDING A TUNGSTEN LAYER

(76) Inventors: Hocine Boubekeur, Dresden (DE); Roman Knoefler, Langebrueck (DE); Hans-Peter Sperlich, Dresden (DE); Clemens Fitz, Dresden (DE); Patrick Minton, Dresden (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 12/052,004

(22) Filed: Mar. 20, 2008

(51) Int. Cl. H01L 21/283; H01L 29/49

(52) U.S. Cl. 257/506; 438/653; 257/E29.158; 257/E21.159

(57) ABSTRACT

A method for producing a layer stack includes providing a tungsten layer, depositing an oxidation barrier layer that immunizes the tungsten layer against oxidation on top of the tungsten layer, and depositing a cap layer on top of the oxidation barrier layer. An integrated circuit is also described.

### BACKGROUND OF THE INVENTION

1. Field of the Invention

The present invention relates to a layer stack including a tungsten layer and to a method for producing a layer stack including a tungsten layer.

2. Description of the Related Art

In the production of tungsten metal gates the oxidation problem of tungsten is very critical. In the presence of oxygen, tungsten can oxidize and form whiskers or hillocks. The most critical production step is the cap nitride deposition, since it is the first high temperature process after the deposition and annealing of tungsten. If oxygen traces are present during this step, an extrusion of tungsten often can not be avoided. This can happen even at very low oxygen concentrations in the range of 10 parts per million and below. The resulting tungsten extrusions can be observed after the nitride deposition as bumps, hillocks or whiskers in the nitride layer. These nitride bumps are critical in later fabrication steps and therefore limit the fabrication yield.

In order to prevent oxidation of the tungsten surface, low temperature load-in can be carried out. Lowering the load-in temperature to 350° C. improves the morphology of the nitride surface. The relatively high temperature difference between the load in temperature and the deposition temperature, however, causes high thermal stress, which is unfavorable. The low load-in temperature also provokes a contamination of the surface with particles.

A second method for suppressing granularity of the nitride film is an in-situ reduction of the tungsten surface with an ammonia purge at around 600° C. The ammonia purge and the low temperature of the purge can, however, lead to a contamination of the tungsten surface with particles since the purge is still at critical temperature. Furthermore, an ammonia purge can lead to an incorporation of nitrogen into the tungsten which results in an unfavorable increase of resistance of the tungsten.

In summary, the outlined methods for suppressing granular growth of nitride films are not suitable for large scale production.

### SUMMARY OF THE INVENTION

Embodiments of the invention provide methods for producing a layer stack. One embodiment includes providing a tungsten layer, depositing an oxidation barrier layer that immunizes (i.e., protects) the tungsten layer against oxidation on top of the tungsten layer, and depositing a cap layer on top of the oxidation barrier layer.

Embodiments of the invention further provide an integrated circuit including a tungsten layer, an oxidation barrier layer covering the tungsten layer, and a cap layer covering the oxidation barrier layer.

### BRIEF DESCRIPTION OF THE DRAWINGS

So that the manner in which the above recited feature of the present invention can be understood in detail, a more particular description of the invention, briefly summarized above, may be had by reference to embodiments, some of which are illustrated in the appending drawing. It is to be noted, however, that the appended drawings illustrate only typical embodiments of this invention and are therefore not to be considered limiting of the scope, for the invention may admit to other equally effective embodiments.

FIG. 1 shows a schematic illustration of a first integrated circuit according to an embodiment of the present invention;

FIG. 2 shows a schematic illustration of a second integrated circuit according to an embodiment of the present invention;

FIG. 3 shows a schematic illustration of a third integrated circuit according to an embodiment of the present invention;

FIG. 4 shows a schematic illustration of a fourth integrated circuit according to an embodiment of the present invention.

### DETAILED DESCRIPTION OF THE PREFERRED EMBODIMENT

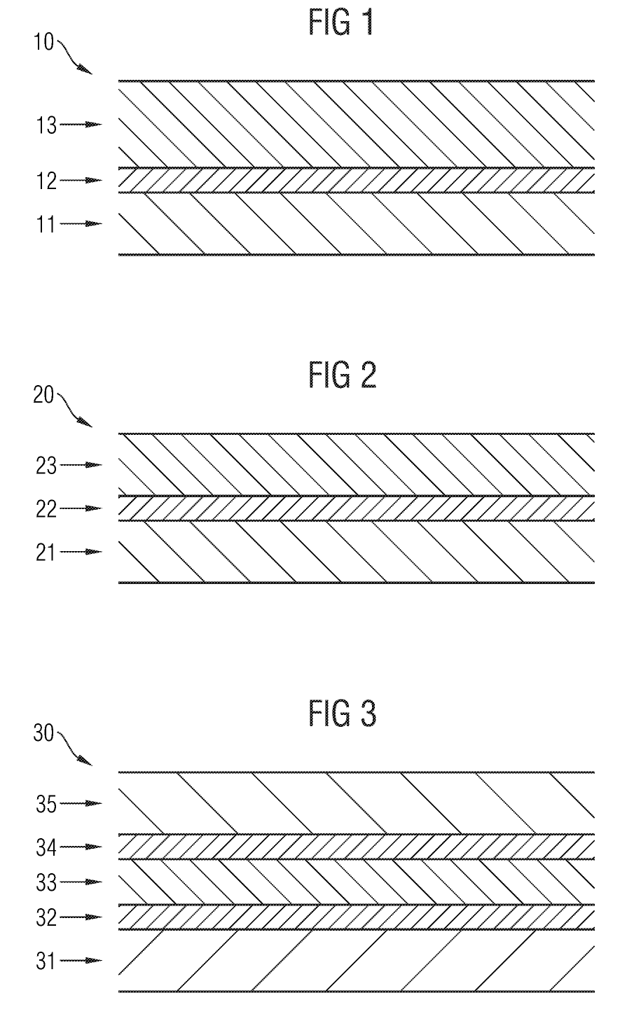

FIG. 1 shows a schematic representation of a portion of an integrated circuit 10 according to one embodiment. The shown portion of the integrated circuit 10 comprises three visible layers 11, 12, 13. The lowermost layer shown in FIG. 1 is a tungsten layer 11. The tungsten layer 11 may for example serve as a gate layer in the integrated circuit 10. The tungsten layer 11 may for example serve as a layer of wordlines in a memory device. The tungsten layer 11 may, however, also be another tungsten layer of the integrated circuit 10. The tungsten layer 11 may be deposited by means of sputtering. The tungsten layer 11 may also be deposited by means of another deposition technique. The tungsten layer 11 may comprise a thickness of 100 nm. The tungsten layer 11 may also comprise a lower or higher thickness according to the specific needs of the application. In another embodiment, layer 11 may also comprise another metal than tungsten that suffers from the oxidation problem.

The tungsten layer 11 is covered by an oxidation barrier layer 12 of silicon nitride. The oxidation barrier layer 12 may also be composed of another kind of nitride. In order to avoid oxidation of the lower lying tungsten layer 11 during the deposition of the oxidation barrier layer 12, the oxidation barrier layer 12 is deposited using plasma enhanced chemical vapor deposition (PECVD) at a temperature below 450° C. according to one embodiment. The deposition temperature may for example be 400° C. The oxidation barrier layer 12 may also be deposited with another deposition technique that avoids oxidation of the tungsten layer 11 and the formation of whiskers and hillocks on the tungsten layer 11. The oxidation barrier layer 12 may comprise a thickness between 10 nm and 30 nm according to one embodiment. The oxidation barrier layer 12 may for example comprise a thickness of 20 nm. The oxidation barrier layer 12 immunizes the subjacent tungsten layer 11 against oxidation. That is, the oxidation barrier layer 12 sufficiently mitigates or eliminates the formation of oxidation tungsten layer 11 under predetermined process conditions.

The oxidation barrier layer 12 is covered by a cap layer 13 of silicon nitride according to one embodiment. The cap layer 13 may also be composed of another kind of nitride or of an oxide. Since the tungsten layer 11 is already immunized against oxidation by the oxidation barrier layer 12, the cap layer 13 may be deposited at high temperature, even in the presence of oxygen traces. The cap layer 13 may for example be deposited in a low pressure chemical vapor deposition (LPCVD) furnace at a temperature above 650° C. according to one embodiment. The cap layer 13 may for example be deposited at a temperature of 780° C. The cap layer 13 may also be deposited by means of another deposition furnace. The cap layer 13 may comprise a thickness between 10 nm and 300 nm according to one embodiment. The cap layer 13 may for example comprise a thickness of 200 nm. The cap layer 13 may be used as a hard mask in a following etching process in the fabrication of the integrated circuit 10.

The deposition of the cap layer 13 may be performed at a higher deposition rate than the deposition of the oxidation barrier 12.

The portion of the integrated circuit 10 depicted in FIG. 1 may for example be part of a multilayered polymetal gate structure of the integrated circuit 10.

FIG. 2 shows a schematic representation of a portion of an integrated circuit 20. The depicted portion of the integrated circuit 20 comprises three visible layers 21, 22, 23. The lowermost layer of the depicted portion of the integrated circuit 20 is a tungsten layer 21. The layer 21 may also be composed out of another metal than tungsten that suffers from the oxidation problem. The tungsten layer 21 may serve as a metal gate layer in the integrated circuit 20. The tungsten layer 21 may for example be a wordline layer in the integrated circuit 20. The tungsten layer 21 may also be any other tungsten layer of the integrated circuit 20. The tungsten layer 21 may be deposited using a sputtering technique. The tungsten layer 21 may also be deposited using another deposition technique. The tungsten layer 21 may for example comprise a thickness of 100 nm according to one embodiment. The tungsten layer 21 may also comprise a lower or higher thickness.

In order to avoid oxidation of the tungsten layer 21 and a formation of whiskers and hillocks during the further processing of the integrated circuit 20, the tungsten layer 21 is covered with an oxidation barrier layer 22 composed out of tungsten nitride. The oxidation barrier layer 22 may be deposited on the tungsten layer 21 by means of sputtering. The oxidation barrier layer 22 may also be deposited by means of another deposition technique. The oxidation barrier layer 22 may be deposited in-situ or ex-situ. The oxidation barrier layer 22 may be deposited on the tungsten layer 21 in the same machine that was used for the deposition of the tungsten layer 21. The oxidation barrier layer 22 may also be deposited in another machine than the one used for the deposition of the tungsten layer 21. The oxidation barrier layer 22 may comprise a thickness between 3 nm and 20 nm according to one embodiment. The oxidation barrier layer 22 may for example comprise a thickness of 7 nm. The oxidation barrier layer 22 immunizes the tungsten layer 21 against oxidation.

In the integrated circuit 20 depicted in FIG. 2, the oxidation barrier layer 22 is covered with a cap layer 23 of silicon nitride. The cap layer 23 may also be composed out of another nitride or an oxide. The cap layer 23 of the integrated circuit 20 may be deposited using a low-pressure chemical vapor deposition (LPCVD) furnace. The LPCVD furnace may for example be a vertical type LPCVD furnace. The cap layer 23 may also be deposited using another kind of furnace or by means of another deposition technique. The cap layer 23 may comprise a thickness between 10 nm and 300 nm according to one embodiment. The cap layer 23 may for example comprise a thickness of 220 nm. The cap layer 23 may be used as a hard mask in an etching process in a following processing step of the integrated circuit 20.

FIG. 3 depicts a schematic representation of a portion of an integrated circuit 30. The depicted portion of the integrated circuit 13 comprises five visible layers 31, 32, 33, 34, 35. The depicted portion of the integrated circuit 30 shows a schematic representation of a multilayered polymetal gate structure.

The lowermost layer depicted in FIG. 3 is a layer 31 of polycrystalline silicon. The polycrystalline silicon layer 31 is covered by a layer 32 of tungsten nitride. The tungsten nitride layer 32 is covered by a layer 33 of tungsten. The tungsten nitride layer 32 is provided between the polycrystalline silicon layer 31 and the tungsten layer 33 as a barrier layer to suppress a silicidation reaction between the tungsten layer 33 and the polycrystalline silicon layer 31. The tungsten nitride layer 32 may comprise a thickness between 3 and 15 nm according to one embodiment. The tungsten nitride layer 32 may for example comprise a thickness of 7 nm. The tungsten nitride layer 32 may be deposited on the layer of polycrystalline silicon 31 by means of sputtering. The tungsten nitride layer 32 may also be deposited by means of another deposition technique.

The tungsten layer 33 may be deposited on the tungsten nitride layer 32 by means of sputtering. The tungsten layer 33 may be deposited on the tungsten nitride layer 32 in-situ or ex-situ. The tungsten layer 33 may comprise a thickness of 30 nm according to one embodiment. The tungsten layer 33 may also comprise a thickness of 100 nm, or any other thickness that is suitable for the application purposes of the integrated circuit 30.

In the integrated circuit 30 depicted in FIG. 3, an oxidation barrier layer 34 composed of tungsten nitride is deposited on top of the tungsten layer 33. The oxidation barrier layer 34 is provided to prevent an oxidation of the tungsten layer 33 and to prevent the formation of whiskers and hillocks on the tungsten layer 33. The oxidation barrier layer 34 may be deposited by means of sputtering. The deposition of the oxidation barrier layer 34 may be performed in-situ or ex-situ. The oxidation barrier layer 34 may also be deposited by means of another deposition technique. The oxidation barrier layer 34 may comprise a thickness between 3 nm and 20 nm according to one embodiment. The oxidation barrier layer 34 may for example comprise a thickness of 7 nm. The oxidation barrier layer 34 immunizes the tungsten layer 33 against oxidation.

In the integrated circuit 30 depicted in FIG. 3, a cap layer 35 composed of silicon nitride covers the oxidation barrier layer 34. Since the tungsten layer 33 is immunized against oxidation by the oxidation barrier layer 34, the cap layer 35 may be deposited in a low pressure chemical vapor deposition furnace at a temperature above 650° C. even in the presence of small traces of oxygen. The cap layer 35 may for example be deposited at a temperature of 780° C. according to a particular embodiment. The cap layer 35 may also be composed of another nitride than silicon nitride or of an oxide. The cap layer 35 may comprise a thickness between 10 nm and 300 nm according to one embodiment. The cap layer 35 may serve as a hard mask in a later etching process during the fabrication of the integrated circuit 30.

The described oxidation barrier layers 12, 22, 34 can be provided between a metal layer and a cap layer in all situations in the fabrication of integrated circuits, when a metal layer has to be immunized against oxidation and formation of whiskers or hillocks before the cap layer is deposited in a furnace process.

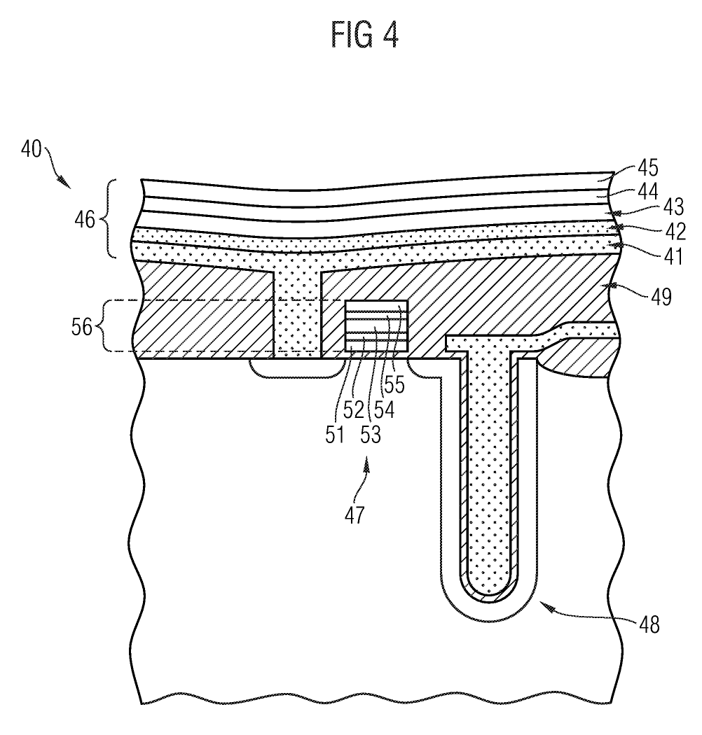

The layer sequences described in the previous figures can for example be used to form wordlines and bitlines in a DRAM memory device. FIG. 4 depicts a schematic representation of a DRAM memory cell 40. The DRAM memory cell 40 is capable of storing one bit of information. The DRAM memory cell 40 comprises a storage capacitor 48. The storage capacitor 48 is provided to store an electric charge that represents the bit value of the DRAM cell 40. The storage capacitor 48 may for example be a trench capacitor. The storage capacitor 48 may also be a stacked capacitor or any other kind of capacitor suitable for the fabrication of DRAM memory cells.

The DRAM cell 40 also comprises a selection transistor 47. The selection transistor 47 may be any kind of transistor suitable for the fabrication of DRAM cells. A gate contact of the selection transistor 47 is connected to a conductive wordline 56. The selection transistor 47 can be switched on and off to connect the storage capacitor 48 to a conductive bitline 46. The selection transistor 47 may be switched on and off by application of a suitable voltage to the wordline 56. If the selection transistor is switched on, the charge stored on the storage capacitor 48 may be detected as a voltage on the bitline 46. If the selection transistor 47 is switched on, the charge stored on the storage capacitor 48 may also be changed by applying a suitable voltage to the bitline 46. The bitline 46, the wordline 56, and the storage capacitor 48 may for example be separated by an insulating oxide layer 49.

The wordline 56 depicted in FIG. 4 comprises a sequence of five visible layers 51, 52, 53, 54, 55 arranged atop of each other. The lowermost layer of the wordline 56 depicted in FIG. 4 is a layer 51 of polycrystalline silicon. The polycrystalline silicon layer 51 is covered by a layer 52 of tungsten nitride. The tungsten nitride layer 52 is covered by a layer 53 of tungsten. The tungsten nitride layer 52 is provided between the polycrystalline silicon layer 51 and the tungsten layer 53 as a barrier layer to suppress a silicidation reaction between the tungsten layer 53 and the polycrystalline silicon layer 51. The tungsten nitride layer 52 may be deposited on the layer of polycrystalline silicon 51 by means of sputtering. The tungsten nitride layer 52 may also be deposited by means of another deposition technique.

The tungsten layer 53 may be deposited on the tungsten nitride layer 52 by means of sputtering. The tungsten layer 53 may be deposited on the tungsten nitride layer 52 in-situ and ex-situ.

The wordline 56 of the DRAM cell 40 depicted in FIG. 4 further comprises an oxidation barrier layer 54 deposited on top of the tungsten layer 53. The oxidation barrier layer 54 is provided to prevent oxidation of the tungsten layer 53 and to prevent the formation of whiskers and hillocks on the tungsten layer 53. The oxidation barrier layer 54 immunizes the tungsten layer 53 against oxidation. The oxidation barrier layer 54 may for example be composed of tungsten nitride. In this case the oxidation barrier layer 54 may be deposited by means of sputtering. The deposition of the oxidation barrier layer 54 may be performed in-situ or ex-situ. The oxidation barrier layer 54 may also be deposited by means of another deposition technique.

The oxidation barrier layer 54 may also be composed of silicon nitride or of another kind of nitride. In this case, in order to avoid oxidation of the lower lying tungsten layer 53 during the deposition of the oxidation barrier layer 54, the oxidation barrier layer 54 may be deposited using PECVD at a temperature below 450° C. The deposition temperature may for example be 400° C. The oxidation barrier layer 54 may also be deposited with another deposition technique that avoids oxidation of the tungsten layer 53 and the formation of whiskers and hillocks on the tungsten layer 53.

In the wordline 56 of the DRAM cell 40 depicted in FIG. 4, a cap layer 55 composed of silicon nitride covers the oxidation barrier layer 54. Since the tungsten layer 53 is immunized against oxidation by the oxidation barrier layer 54, the cap layer 55 may be deposited in a LPCVD furnace at a temperature above 650° C. even in the presence of small traces of oxygen. The cap layer 55 may for example be deposited at a temperature of 750° C. The cap layer 55 may also be composed of another nitride than silicon nitride or of an oxide.

The bitline 46 of the DRAM cell 40 shown in FIG. 4 comprises five visible layers 41, 42, 43, 44, 45 arranged atop of each other. The lowermost layer of the bitline 46 is a layer 41 of polycrystalline silicon. The polycrystalline silicon layer 41 is covered by a layer 42 of tungsten nitride. The tungsten nitride layer 42 is covered by a layer 43 of tungsten. The tungsten nitride layer 42 is provided between the polycrystalline silicon layer 41 and the tungsten layer 43 as a barrier layer to suppress a silicidation reaction between the tungsten layer 43 and the polycrystalline silicon layer 41. The tungsten nitride layer 42 may be deposited on the layer of polycrystalline silicon 41 by means of sputtering. The tungsten nitride layer 42 may also be deposited by means of another deposition technique.

The tungsten layer 43 may be deposited on the tungsten nitride layer 42 by means of sputtering. The tungsten nitride layer 43 may be deposited on the tungsten nitride layer 42 in-situ or ex-situ.

An oxidation barrier layer 44 is deposited on top of the tungsten layer 43 of the bitline 46 of the DRAM cell 40 depicted in FIG. 4. The oxidation barrier layer 44 is provided to prevent oxidation of the tungsten layer 43 and to prevent the formation of whiskers and hillocks on the tungsten layer 43. The oxidation barrier layer 44 immunizes the tungsten layer 43 against oxidation. The oxidation barrier layer 44 may be composed of silicon nitride or of another kind of nitride. In order to avoid oxidation of lower lying tungsten layer 43 during the deposition of the oxidation barrier layer 44, the oxidation barrier layer 44 may be deposited using PECVD at a temperature below 450° C. The deposition temperature may for example be 400° C. The oxidation barrier layer 44 may also be deposited with another deposition technique that avoids oxidation of the tungsten layer 43 and the formation of whiskers and hillocks on the tungsten layer 43.

The oxidation barrier layer 44 may also be composed of tungsten nitride. In this case, the oxidation barrier layer 44 may be deposited by means of sputtering. The sputtering of the oxidation barrier layer 44 may be performed in-situ or ex-situ.

In the bitline 46 of the DRAM cell 40 depicted in FIG. 4, a cap layer 45 composed of silicon nitride covers the oxidation barrier layer 44. Since the tungsten layer 43 is immunized against oxidation by the oxidation barrier layer 44, the cap layer 45 may be deposited in a LPCVD furnace at a temperature above 650° C., even in the presence of small traces of oxygen. The cap layer 45 may for example be deposited at a temperature of 780° C. The cap layer 45 may also be composed of another nitride than silicon nitride or of an oxide. The cap layer 45 may serve as a hard mask in a later etch process during the fabrication of the DRAM cell 40.

The bitline 46 and the wordline 56 of the DRAM cell 40 shown in FIG. 4 do not necessarily need to comprise the same sequence of layers.

While the foregoing is directed to embodiments of the present invention, other and further embodiments of the present invention may be devised without departing from the basic scope thereof, and the scope thereof is determined by the claims that follow.

What is claimed is:

1. A method for producing a layer stack, comprising:
providing a tungsten layer;
depositing an oxidation barrier layer on top of the tungsten layer, wherein the oxidation barrier layer immunizes the tungsten layer against oxidation; and
depositing a cap layer on top of the oxidation barrier layer.

2. The method as claimed in claim 1, wherein the oxidation barrier layer and the cap layer comprise a total thickness between 20 nm and 300 nm.

3. The method as claimed in claim 1, wherein the cap layer is used as a hard mask in a following etch process or as etch stop liner.

4. The method as claimed in claim 1, wherein the oxidation barrier layer comprises a tungsten compound.

5. The method as claimed in claim 4, wherein the oxidation barrier layer comprises tungsten nitride.

6. The method as claimed in claim 1, wherein the oxidation barrier layer comprises a thickness between 3 nm and 20 nm.

7. The method as claimed in claim 1, wherein the oxidation barrier layer comprises a silicon compound.

8. The method as claimed in claim 7, wherein the oxidation barrier layer comprises silicon nitride.

9. The method as claimed in claim 1, wherein the oxidation barrier layer is deposited at a temperature below 450° C.

10. The method as claimed in claim 1, wherein the oxidation barrier layer is deposited using plasma enhanced chemical vapor deposition.

11. The method as claimed in claim 1, wherein the oxidation barrier layer comprises a thickness between 10 nm and 30 nm.

12. A method for producing a layer stack, comprising:
providing a tungsten gate electrode layer;
depositing an oxidation barrier layer of silicon nitride at a first temperature with a first deposition rate on top of the tungsten gate electrode layer; and
depositing a cap layer of silicon nitride at a second temperature with a second deposition rate on top of the oxidation barrier layer.

13. The method as claimed in claim 12, wherein the first temperature is lower than the second temperature.

14. The method as claimed in claim 12, wherein the first deposition rate is lower than the second deposition rate.

15. The method as claimed in claim 12, wherein the cap layer is deposited at a temperature above 650° C., wherein the cap layer is deposited using low-pressure chemical vapor deposition.

16. A method for producing a layer stack, comprising:
providing a tungsten gate electrode layer;
depositing an oxidation barrier layer of tungsten nitride on top of the tungsten gate electrode layer; and
depositing a cap layer of silicon nitride on top of the oxidation barrier layer.

17. The method as claimed in claim 16, wherein the cap layer is deposited at a temperature above 650° C., wherein the cap layer is deposited using low-pressure chemical vapor deposition.

18. The method as claimed in claim 16, wherein the oxidation barrier layer is deposited using sputtering.

19. An integrated circuit, comprising:
a tungsten layer;
an oxidation barrier layer covering the tungsten layer; and
a cap layer covering the oxidation barrier layer.

20. The integrated circuit as claimed in claim 19, wherein the tungsten layer is provided as a gate electrode layer.

21. The integrated circuit as claimed in claim 19, wherein the cap layer comprises silicon nitride.

22. The integrated circuit as claimed in claim 19, wherein the oxidation barrier layer and the cap layer comprise a total thickness between 20 nm and 300 nm.

23. The integrated circuit as claimed in claim 19, wherein the oxidation barrier layer is a silicon nitride layer.

24. The integrated circuit as claimed in claim 19, wherein the oxidation barrier layer comprises a thickness between 10 nm and 30 nm.

25. The integrated circuit as claimed in claim 19, wherein the oxidation barrier layer is a tungsten nitride layer.

26. The integrated circuit as claimed in claim 19, wherein the oxidation barrier layer comprises a thickness between 3 nm and 20 nm.
